(19) United States
(12) Patent Application Publication
(10) Pub. No.: US 2005/0179379 A1
(43) Pub. Date: Aug. 18, 2005

(54) Organic light-emitting device having thin-film encapsulation portion, method of manufacturing the device, and apparatus for forming a film

(76) Inventor: Han-Ki Kim, Yongin-si (KR)

Correspondence Address: Robert E. Bushnell, Suite 300, 1522 K Street, N.W., Washington, DC, 20005-1202, US

(21) Appl. No.: 11/059,531

(22) Filed: Feb. 17, 2005

(30) Foreign Application Priority Data
Feb. 17, 2004 (KR) 2004-10415

(51) Int. Cl. H05B 33/04; H05B 33/10

(52) U.S. Cl. 313/512; 313/504; 313/503; 445/25

(57) ABSTRACT

An organic light-emitting device that includes an encapsulation structure that has excellent resistance to water, heat, and chemicals and can be mass-produced, a method of manufacturing the device, and an apparatus for manufacturing the encapsulation structure. The organic light-emitting device includes a substrate, an organic light-emitting portion that has an organic light-emitting diode (OLED) and formed on a surface of the substrate, and an encapsulation structure made of a parylene polymer and formed to cover the organic light-emitting portion.

### CLAIM OF PRIORITY

This application makes reference to, incorporates the same herein, and claims all benefits accruing under 35 U.S.C. §119 from an application for ORGANIC LIGHT-EMITTING DEVICE HAVING THIN-FILM ENCAPSULATION PORTION, METHOD OF MANUFACTURING THE DEVICE, AND APPARATUS FOR FORMING A FILM earlier filed in the Korean Intellectual Property Office on 17 Feb. 2004 and there duly assigned Serial No. 2004-10415.

### BACKGROUND OF THE INVENTION

1. Field of the Invention

The present invention relates to an organic light-emitting device having a thin-film encapsulation portion, a method of manufacturing the device, and an apparatus for forming the encapsulation portion, and more particularly, to an organic light-emitting device having an encapsulation portion made of a parylene polymer, a method of manufacturing the device, and an apparatus for making the parylene polymer film.

2. Description of the Related Art

Generally, flat panel displays, such as organic light-emitting devices, TFT-LCDs, etc. can be made ultra-thin and flexible due to their operational characteristics. Flexible substrates are required to make flat panel displays thinner and more flexible. Generally, flexible substrates are made of synthetic resins. However, when manufacturing flat panel displays, the formation of organic layers, a TFT layer, electrode layers, or an orientation layer, etc. for flat panel displays is difficult, complex and expensive. Thus, when the substrates are made of synthetic resins, the substrates or thin layers formed on the substrates may be deformed according to the operational conditions.

To overcome this problem, Japanese Laid-Open Patent Publication No. 2000-123971 describes a method of manufacturing an organic light-emitting device using a substrate made of a waterproof-treated film. The organic light-emitting device includes two insulating substrates arranged opposite to each other, at least one of the substrates being flexible and at least one of the substrates having high light transmittance, an electrode layer formed on each of the inner sides of the substrates, and an organic layer having a light-emitting layer that is sandwiched between the electrodes. The organic light-emitting device is manufactured by layering an electrode layer and an organic layer on one substrate, layering an electrode layer and an organic layer, that is of the same type as the above organic layer, on the other substrate, and adhering closely the substrates to each together so that the organic layers are connected to each other, and then sealing the substrates together.

Japanese Laid-Open Patent Publication No. Hei 9-7763 describes another method of manufacturing an organic light-emitting device. The organic light-emitting device is manufactured by layering a transparent anode electrode layer and an organic thin layer on a waterproof film, layering a cathode electrode layer and an organic thin layer on another waterproof film, and connecting both waterproof films to each other and sealing them together. To increase the attachment between the connected surfaces, both waterproof films are connected to each other by pressing them using a resin dispersion layer therebetween at a flexible temperature of a resin binder, the resin dispersion layer being obtained by dispersing an organic material in the resin binder. However, in the above organic light-emitting device, the organic thin layers are separately produced, and thus cannot be easily aligned at the time of connecting both waterproof films. In addition, the attachment of an organic layer having a specific pattern may not be increased.

U.S. Pat. No. 6,426,274 describes a method of making a thin film semiconductor. The method includes forming porous layers having different pore sizes on a surface layer of a substrate, forming an epitaxial semiconductor film on the top porous layer, and separating the epitaxial semiconductor film from the substrate using the porous layers. U.S. Pat. Nos. 6,326,280, 6,107,213, 5,811,348, 6,194,245, and 6,194,239 describe methods of making a thin film semiconductor and methods of separating an element forming layer from a base body.

U.S. Pat. Nos. 6,268,695 and 6,497,598 describe an organic light-emitting device having polymer layers with a ceramic layer sandwiched inbetween as an encapsulation structure and a method of making the encapsulation structure, respectively. U.S. Pat. No. 6,413,645 describes an organic light-emitting device having at least one polymer layer and at least one inorganic layer as an encapsulation structure. U.S. Pat. No. 6,522,067 describes an organic light-emitting device having at least one barrier layer and at least one polymer layer as an encapsulation structure. U.S. Pat. No. 6,548,912 describes a micro-electronic device having at least one barrier layer and at least one polymer layer as an encapsulation structure. U.S. Pat. No. 6,570,325 describes an organic light-emitting device having decoupling layers with a barrier layer sandwiched inbetween as an encapsulation structure. U.S. Pat. No. 6,573,652 describes a display device having at least one barrier layer and at least one polymer layer as an encapsulation structure.

The display devices described above use a film-type encapsulation structure in order to make the devices thinner. However, the use of this structure in front emission type devices is limiting since light is emitted in an opposite direction to the substrate on which an organic layer is formed, i.e., in a direction toward the encapsulation structure in the front emission type devices. The thin-film encapsulation structure described above cannot efficiently protect the light producing organic layer from moisture or air. To protect the organic layer from moisture and air, the encapsulation structure must be very thick.

An encapsulation layer made of silicon nitride or silicon oxynitride has a dense structure and thus provides excellent resistance to moisture. However, the organic layer may be adversely affected by the production process of the encapsulation layer. When silicon nitride or silicon oxynitride is used in high density plasma-chemical vapor deposition (HDP-CVD) or catalytic-chemical vapor deposition (CAT-CVD), the temperature of the substrate rises due to a high density plasma, and thus, the characteristics of the organic layer are changed, causing deterioration of the characteristics of the OLED.

A method of depositing silicon nitride or silicon oxynitride at a low temperature has been explored. However, since the layer of silicon nitride or silicon oxynitride is grown at a low temperature, the growth rate is low resulting in low throughput. Further, to serve as an encapsulation layer, the silicon nitride or silicon oxynitride should be formed as a dense structure by growing them as a thin layer at a high temperature. However, since the OLED cannot be heated to 100° C. or higher, there is a limitation regarding realizing a dense encapsulation layer of silicon nitride or silicon oxynitride without exposing the organic layer to extreme heat. When silicon nitride is grown to a thick encapsulation layer at a low temperature, cracks occur in the encapsulation layer due to a tensile stress applied thereto, and thus, the encapsulation layer loses its function. What is therefore needed is an encapsulation layer for an OLED that overcomes the above problems.

### SUMMARY OF THE INVENTION

It is therefore an object of the present invention to provide an improved design for an OLED.

It is also an object of the present invention to provide a method for making the novel OLED.

It is further an object of the present invention to provide an apparatus used to make the novel OLED.

It is still an object of the present invention to provide a design for an OLED having an encapsulation layer that protects an organic layer from outside moisture.

It is further an object of the present invention to provide a method for making the novel OLED that does not harm the organic layer.

It is still an object of the present invention to provide a design for an OLED having an encapsulating layer that prevents moisture from reaching the organic layer while being transparent to visible light.

It is further an object of the present invention to provide a design for an OLED that is flexible or bendable while protecting the organic layer from moisture.

It is further an object of the present invention to provide a method for making and apparatus for making the novel OLED that leads to low production costs.

It is also an object of the present invention to provide a design for an OLED that leads to a display having a longer lifespan.

It is still an object of the present invention to provide a design for an OLED that leads to more efficient conversion of electrical signals into visible images.

It is further an object of the present invention tp provide an organic light-emitting device that has an encapsulation structure that has excellent resistance to water, heat, and chemicals and can be mass-produced, a method of manufacturing the device, and an apparatus for forming the encapsulation structure.

These and other objects can be achieved by an organic light-emitting device that includes a substrate, an organic light-emitting portion having an organic light-emitting diode (OLED) and formed on a surface of the substrate, and an encapsulation portion made of a parylene polymer and formed to cover the organic light-emitting portion.

The OLED may include a first electrode layer, an organic layer at least including an organic light-emitting layer, and a second electrode layer sequentially formed on the substrate, the first electrode layer being transparent. The OLED may include a first electrode layer, an organic layer at least including an organic light-emitting layer, and a second electrode layer sequentially formed on the substrate, the second electrode layer being transparent. The parylene polymer may be made of parylene N, parylene D, or parylene C.

The organic light-emitting device may further include a protective layer covering the organic light-emitting portion and made of silicon oxide, silicon nitride, or silicon oxynitride. The substrate may further include at least one thin film transistor.

According to another aspect of the present invention, there is provided a method of manufacturing an organic light-emitting device, by forming at least one organic light-emitting portion having an OLED on a surface of a substrate, vaporizing a parylene powder by heating to form a gaseous parylene monomer, and depositing the gaseous parylene monomer on the at least one organic light-emitting portion to form an encapsulation portion made of the parylene polymer.

The forming the gaseous parylene monomer may involve vaporizing the parylene powder to a parylene dimer form by heating, and pyrolizing the parylene dimer to its monomer form by heating. The vaporizing the parylene powder may be performed by heating the parylene powder to 130 to 200° C. The pyrolizing the parylene dimer may be performed by heating the parylene dimer to 500 to 700° C. The method may further include depositing a protective layer to cover the organic light-emitting portion, the protective layer being made of silicon oxide, silicon nitride, or silicon oxynitride.

According to another aspect of the present invention, there is provided an apparatus for forming a film that has at least one heating unit for heating the parylene powder to form a gaseous parylene monomer, and at least one first deposition unit that contains a substrate and communicates with the heating unit such that the parylene monomer is condensed on a surface of the substrate.

The at least one heating unit may include a first heating unit for vaporizing the parylene powder to the parylene dimer form by heating, and a second heating unit for pyrolizing the parylene dimer to its monomer form. The first heating unit and the second heating unit may be sequentially connected to the first deposition unit. The first heating unit and the second heating unit may be installed within the first deposition unit. The apparatus may further include a liquid cold trap for trapping an undeposited parylene molecule, the liquid cold trap communicating with the first deposition unit. The first deposition unit may be insulated from the heating unit.

The apparatus may further include a second deposition unit for depositing a protective layer that is made of silicon oxide, silicon nitride, or silicon oxynitride on the substrate, the second deposition unit communicating with the heating unit or the first deposition unit.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a cross-sectional view of an organic light-emitting device according to an embodiment of the present invention;

FIG. 2 is a detailed cross-sectional view of a passive matrix organic light-emitting portion illustrated in FIG. 1 according to an embodiment of the present invention;

FIG. 3 is a detailed cross-sectional view of another passive matrix organic light-emitting portion illustrated in FIG. 1 according to another embodiment of the present invention;

FIG. 4 is a detailed cross-sectional view of an active matrix organic light-emitting portion illustrated in FIG. 1 in an active matrix device according to still another embodiment of the present invention;

FIG. 5 is a detailed cross-sectional view of another active matrix organic light-emitting portion illustrated in FIG. 1 in an active matrix device according to yet another embodiment of the present invention; and

FIGS. 6 through 10 are views illustrating the structures of apparatuses for forming films according to embodiments of the present invention.

### DETAILED DESCRIPTION OF THE INVENTION

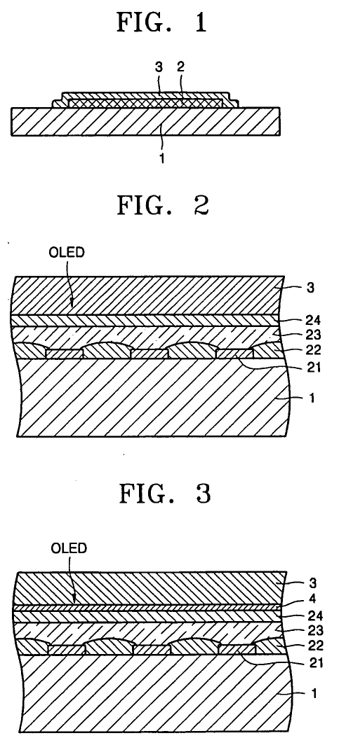

Turning now to the figures, FIG. 1 is a cross-sectional view of an ultra-thin organic light-emitting device according to an embodiment of the present invention. Referring to FIG. 1, the ultra-thin organic light-emitting device includes a substrate 1, an organic light-emitting portion 2 including an organic light-emitting diode (OLED) formed on a surface of the substrate 1, and an encapsulation portion 3 formed to encapsulate the organic light-emitting portion 2. The substrate 1 may be made of a transparent glass. The substrate 1 may also be made of flexible plastics or metals. A buffer layer may be formed on the top surface of the substrate 1.

The organic light-emitting portion 2 includes the OLED and realizes a predetermined image. Various types of OLEDs may be used in the organic light-emitting portion 2. That is, any one of a passive matrix (PM) type OLED, that is simple matrix type, and an active matrix (AM) type OLED, that includes a thin film transistor (TFT) layer, may be used.

Turning to FIGS. 2 and 3, FIGS. 2 and 3 are detailed cross-sectional views of the ultra-thin organic light-emitting device of FIG. 1 in passive matrix form according to embodiments of the present invention. Referring to FIGS. 2 and 3, a first electrode layer 21 is formed in a striped pattern on a glass substrate 1 and an organic layer 23 and a second electrode layer 24 are sequentially formed on the first electrode layer 21. An insulating layer 22 may be further formed between every striped line of the first electrode layer 21 and the second electrode layer 24 may be formed in a pattern perpendicular to the pattern of the first electrode layer 21.

The organic layer 23 may be a low molecular or high molecular organic layer. The low molecular organic layer may have a single or multi-laminated structure of a hole injection layer (HIL), a hole transport layer (HTL), an organic emission layer (EML), an electron transport layer (ETL), an electron injection layer (EIL), etc. Various organic materials, such as, copper phthalocyanine (CuPc), N,N′-di(naphthalene-1-yl)-N,N′-diphenyl-benzidine (NPB), tris-8-hydroxyquinoline aluminum (Alq3), etc. maybe used for the low molecular organic layer. The low molecular organic layer may be formed by vacuum deposition.

The high molecular organic layer may have a structure made of an HTL and an EML. In this case, the HTL may be made of poly(ethylenedioxy)thiophene (PEDOT) and the EML may be made of a high molecular weight organic material, such as poly(phenylene vinylene) (PPV) and polyfluorene. The HTL and the EML may be formed by screen printing or ink-jet printing.

In a full-color organic light-emitting device, the organic layer 23 may be made of red (R), green (G), and blue (B) pixels. The first electrode layer 21 functions as an anode electrode and the second electrode layer 24 functions as a cathode electrode, or vice versa. The first electrode layer 21 may be a transparent electrode or a reflective electrode. The transparent electrode may be made of ITO, IZO, ZnO, or In₂O₃. The reflective electrode may be obtained by forming a reflective layer using Ag, Mg, Al, Pt, Pd, Au, Ni, Nd, Ir, Cr, or a compound thereof and forming a layer using ITO, IZO, ZnO, or In₂O₃ on the reflective layer.

The second electrode layer 24 may be a transparent electrode or a reflective electrode. When the transparent electrode is used as the second electrode layer 24, the second electrode layer 24 functions as a cathode electrode. In this case, a low work function metal, i.e., Li, Ca, LiF/Ca, LiF/Al, Al, Ag, or Mg, or a compound thereof, is deposited toward the direction of the organic layer 23 and then, a material used for forming a transparent electrode, such as ITO, IZO, ZnO, or In₂O₃ may be formed on the deposited low work function metal. The reflective electrode may be formed using Li, Ca, LiF/Ca, LiF/Al, Al, Ag, Mg, and compounds thereof by deposition. Barrier rib elements maybe further formed on the insulating layer 22 in order to pattern the organic layer 23 and the second electrode layer 24 in predetermined patterns. An encapsulation portion 3 is formed on the second electrode layer 24 to cover the organic light-emitting portion 2, as illustrated in FIG. 1. The encapsulation portion 3 may be made of a parylene polymer.

The term “parylene” refers to a polymer pertaining to a poly-para-xylylene based polymer. Parylene has excellent resistance to water, heat, and chemicals and high transmittance and refractive index. Further, problems due to the use of a conventional material such as silicon nitride or silicon oxynitride in the encapsulation layer can be overcome by using an encapsulation layer made of parylene, and parylene has excellent flexibility such that the encapsulation layer made of parylene can have an excellent function as a flexible encapsulation layer in an organic light-emitting device. Examples of the parylene polymer include, but are not limited to parylene N, parylene D, or parylene C.

A protective layer 4 may be further formed on an inner side of the encapsulation portion 3 as illustrated in FIG. 3 or an outer side of the encapsulation portion 3, and the protective layer 4 can be made of silicon oxide, silicon nitride or silicon oxynitride. Although FIG. 3 illustrates a structure in that the protective layer 4 is sandwiched between the encapsulation portion 3 and the second electrode layer 24, the structure including the protective layer 4 is not limited thereto and the protective layer 4 may be formed on the top surface of the encapsulation portion 3.

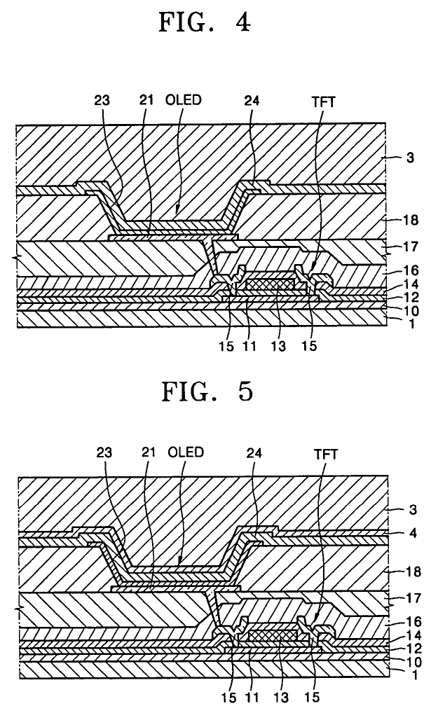

Turning to FIGS. 4 and 5, FIGS. 4 and 5 are detailed cross-sectional views of the ultra-thin organic light-emitting device of FIG. 1 in an active matrix form according to embodiments of the present invention. Referring to FIGS. 4 and 5, each pixel of the organic light-emitting portion 2 in FIG. 1 has a TFT and an OLED that is a self light-emitting diode. The structure of the TFT is not limited to that illustrated in FIGS. 4 and 5 and various changes in the number and the structure of the TFT may be made. The AM type OLED will be now described in detail.

FIG. 4 illustrates a sub-pixel of the organic light-emitting portion 2. As illustrated in FIG. 4, a buffer layer 10 is formed on a substrate 1 that is made of glass, plastic, or metal and the TFT and the OLED are formed above the buffer layer 10. An active layer 11 having a predetermined pattern is formed on the buffer layer 10. A gate insulating layer 12 is formed on the active layer 11 and the gate insulating layer 12 may be made of silicon oxide, silicon nitride, silicon oxynitride, or organic insulator, etc. A gate electrode 13 is formed on a predetermined region on the gate insulating layer 12. The gate electrode 13 is connected to a gate line (not illustrated) that applies a TFT on/off signal to the gate electrode 13. An interlayer insulating layer 14 is formed on the gate electrode 13 and source/drain electrodes 15 are respectively formed to contact source/drain regions of the active layer 11 through contact holes. A passivation layer 16 is formed on the source/drain electrodes 15. The passivation layer 16 is made of silicon oxide, silicon nitride, or silicon oxynitride, etc. A planarization layer 17 is formed on the passivation layer 16. The planarization layer 17 is made of an organic material, such as acryl, polyimide, BCB, etc. At least one capacitor is connected to the TFT, although it is not illustrated in FIGS. 4 and 5.

A first electrode layer 21, that is an anode electrode of the OLED, is formed on the planarization layer 17 and a pixel define layer 18 made of an organic material is formed to cover the first electrode layer 21. After a predetermined opening is formed in the pixel define layer 18, an organic layer 23 is formed in a region defined by the opening. The organic layer 23 includes a light-emitting layer.

The OLED emits red, green, or blue light according to an electrical current to indicate predetermined image information. The OLED includes the first electrode layer 21 that is connected to the drain electrode 15 of the TFT and is supplied with a positive voltage from the drain electrode 15, a second electrode layer 24 that covers the entire pixel and supplies a negative voltage to the organic layer 23, and the organic layer 23 that is sandwiched between the first electrode layer 21 and the second electrode layer 24 and emits light. The first electrode layer 21 and the second electrode layer 24 are insulated from each other by the organic layer 23 and apply voltages having different polarities to the organic layer 23, so that the organic layer 23 can emit light.

The first electrode layer 21, the second electrode layer 24 and the organic layer 23 are identical to those in the PM type OLEDs illustrated in FIGS. 2 and 3, except that the first electrode layer 21 may be patterned in a pixel unit and the second electrode layer 24 may be patterned to cover all the organic light-emitting portion 2, and their detailed descriptions will not repeated.

This AM type OLED may include an encapsulation portion 3 that is made of a parylene polymer and formed on the second electrode layer 24, as illustrated in FIG. 4, and may further include a protective layer 4 that is made of silicon oxide, silicon nitride, or silicon oxynitride, etc., as illustrated in FIG. 5. The encapsulation portion 3 has the identical functional effects as in the embodiments illustrated in FIGS. 2 and 3.

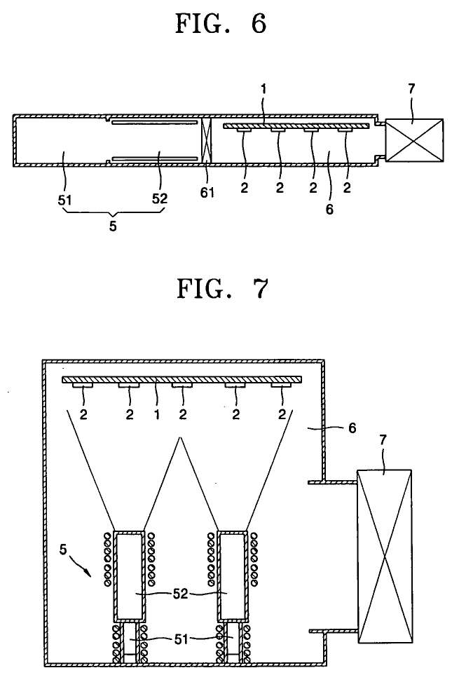

The encapsulation portion 3 made of the parylene polymer may be deposited to cover the organic light-emitting portion 2 using an apparatus for forming a film, as illustrated in FIGS. 6 through 10. The apparatus for forming a film according to embodiments of the present invention will now be described in more detail.

Turning to FIG. 6, FIG. 6 is a view illustrating the structure of an apparatus for forming the encapsulation portion 3 (or encapsulation film or encapsulation layer) according to an embodiment of the present invention. Referring to FIG. 6, the apparatus includes a heating unit 5 for heating a parylene powder to form a gaseous parylene monomer and a first deposition unit 6 that contains a substrate and communicates with the heating unit 5 such that the parylene monomer is condensed on a surface of the substrate 1. Prior to deposition, the substrate has an organic light-emitting portion 2 formed thereon. The encapsulation film 3 is formed over the organic light-emitting portion 2 on the substrate 1.

The heating unit 5 includes a first heating unit 51 for vaporizing the parylene powder to the parylene dimer form by a first heating and a second heating unit 52 for pyrolizing the parylene dimer to its monomer form. Thus, there is a two step process where the parylene powder is first converted to a parylene dimer by a first heating and then the parylene dimer is converted to a gaseous parylene monomer by a second heating or pyrolizing. It is this gaseous parylene monomer that condenses on the substrate 1 with the organic light-emitting portion 2 to form the encapsulation portion 3 over the organic light-emitting portion 2.

The first heating unit 51 is a zone for preheating the parylene powder. In the first heating unit 51, the temperature is maintained at 130 to 200° C. to vaporize the parylene powder to the gaseous parylene dimer. The second heating unit 52 is a zone for pyrolizing the parylene dimer. In the second heating unit 52, the temperature is maintained at 500 to 700° C. to pyrolize the vaporized gaseous parylene dimer to its gaseous monomer form.

The first deposition unit 6 is maintained at a low temperature and the gaseous parylene monomer is condensed on the substrate I to form an encapsulation portion made of the parylene polymer. The first deposition unit 6 is insulated from the heating unit 5. An insulating door 61 is located between the first deposition unit 6 and the heating unit 5 to keep the first deposition unit cool enough so that condensation of the gaseous parylene monomer can occur. The apparatus may further include a liquid cold trap 7 that communicates with the first deposition unit 6 to trap undeposited parylene molecules from the first deposition unit 6.

According to the embodiment illustrated in FIG. 6, the second heating unit 52 and the first heating unit 51 are sequentially connected to the first deposition unit 6. However, the structure of the apparatus is not limited thereto and may include the structure illustrated in FIG. 7.

Turning now to FIG. 7, FIG. 7 is a view illustrating the structure of an apparatus for forming a film according to another embodiment of the present invention. Referring to FIG. 7, a plurality of heating units 5 are installed within a first deposition unit 6. The apparatus may further include an insulating structure (not illustrated) between the heating units 5 and a substrate 1. Of course, the insulating structure excludes a region through which a gaseous parylene monomer is ejected. The other structures are the same as illustrated in FIG. 6 and their detailed descriptions will not be repeated.

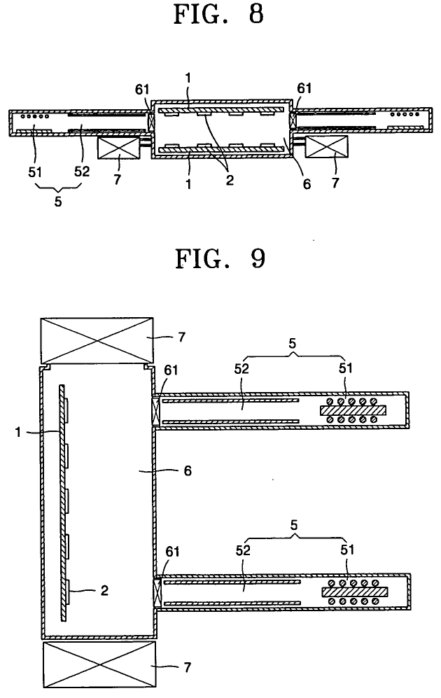

Turning now to FIG. 8, FIG. 8 is a view illustrating the structure of an apparatus for forming a film according to still another embodiment of the present invention. Referring to FIG. 8, two substrates (each reference numeral 1) are loaded up and down in a first deposition unit 6. Heating units 5 are located at opposite ends of the first deposition unit 6.

In FIG. 8, the parylene monomer is supplied to first deposition unit 6 at both sides, and thus, a rapid growth rate of the parylene polymer can be ensured. Also, the parylene monomer exiting second heating units 52 condense on the substrates 1 which are held at relatively low temperatures. The substrates 1 in the first deposition unit 6 in FIG. 8 are arranged along an upper and a lower side of the first deposition unit, thus improving productivity. At this time, the growth speed can be adjusted by controlling electrical currents of heaters in the second heating units 52. Liquid cold traps 7 that communicate with the first deposition unit 6 trap undeposited parylene molecules from the first deposition unit 6, as described in the embodiment illustrated in FIGS. 6 and 7.

Turning now to FIG. 9, FIG. 9 is a view illustrating the structure of an apparatus for forming a film according to yet another embodiment of the present invention, where a parylene layer is deposited on substrates that are arranged vertically. Referring to FIG. 9, two heating units 5 are connected in a row (horizontally) to a first deposition unit 6, each heating unit 5 includes a first heating unit 51 and a second heating unit 52 that are linearly (horizontally) arranged. Insulating doors 61 are located between each heating unit 5 and the first deposition unit 6 to ensure thermal isolation between the first deposition unit 6 and each heating unit 5.

In FIG. 9, a large substrate 1 may be vertically oriented in the first deposition unit 6 and a parylene monomer travels vertically within the first deposition unit to ensure a large deposition area. In addition, by increasing the number of a monomer supply unit for supplying the parylene monomer, i.e., the heating unit 5, deposition of the encapsulation portion in a large OLED or large flexible OLED can be performed easily using the apparatus of FIG. 9. Liquid cold traps 7 may be installed above and below the first deposition unit 6 to trap undeposited parylene monomer from the first deposition unit 6.

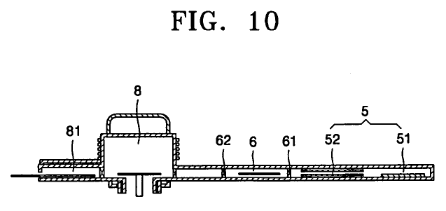

Turning now to FIG. 10, FIG. 10 is a view illustrating the structure of an apparatus for forming a film according to yet another embodiment of the present invention, the structure further including a second deposition unit 8 for depositing a protective layer 4 made of silicon oxide, silicon nitride or silicon oxynitride.

A deposition unit for HDP-CVD may be used as the second deposition unit 8 and a loading unit 81 for loading a substrate is connected to one side of the second deposition unit 8 and a first deposition unit 6 is connected to the opposite side of the second deposition unit 8. The first deposition unit 6 may be anyone of those illustrated in FIGS. 6 through 9, as well as that illustrated in FIG. 10. A further insulating door 62 may be located between the first deposition unit 6 and the second deposition unit 8 to protect the first deposition unit 6 from heat.

Although in an operational process, the second deposition unit 8 is located closer to the loading unit 81 than the first deposition unit 6 in FIG. 10, the second deposition unit 8 may instead be located further from the loading unit 81 than the first deposition unit 6. The first deposition unit 6 and the second deposition unit 8 may be in-line installed (or integrated together) as described above. Alternatively, they may be separately installed.

A method of manufacturing an organic light-emitting device using the apparatus for forming a film will now be described. First, the organic light-emitting portion 2 is formed on the substrate 1 as illustrated in FIG. 1. The organic light-emitting portion 2 may be the PM type illustrated in FIGS. 2 and 3 or the AM type illustrated in FIGS. 4 and 5. A plurality of separate organic light-emitting portions 2 may be formed on the substrate 1. The organic light-emitting portion 2 may be formed using a conventional method of manufacturing a PM type organic light-emitting portion or an AM type organic light-emitting portion.

After forming the organic light-emitting portion 2 on the substrate 1, the encapsulation portion 3 is deposited on the second electrode layer 24 of the organic light-emitting portion 2. The encapsulation portion 3 may be formed using one of the apparatuses illustrated in FIGS. 6 through 10.

First, the substrate 1 having the organic light-emitting portion 2 formed thereon is loaded in the first deposition unit 6. Then, the parylene polymer is deposited to cover the organic light-emitting portion 2 on the substrate 1 in the first deposition unit 6.

When the parylene powder is preheated to about 130 to 200° C. in the first heating unit 51, the parylene powder is vaporized to a parylene dimer form represented by formula 1:

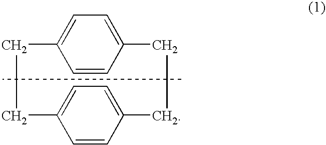

Then, when the vaporized parylene dimer is passed through the second heating unit 52 maintained at about 500 to 700° C., the parylene dimer is pyrolized to a gaseous parylene monomer form as represented by formula 2:

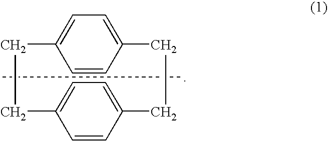

When the gaseous parylene monomer is formed as described above, the insulating door 61 is opened to allow the gaseous parylene monomer to flow into the first deposition unit 6 maintained at a low temperature, and then the insulating door 61 is closed. If the heating unit 5 is installed in the first deposition unit 6 as illustrated in FIG. 7, there is no need to separately open and close the insulating door 61, etc.

When the gaseous parylene monomer flown into the first deposition unit 6 is condensed on the substrate 1 containing the organic light-emitting portion(s) 2 that is maintained at a low temperature, the encapsulation portion 3 made of the parylene polymer is formed, the parylene polymer being represented by formula 3 and having excellent resistance to water:

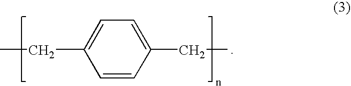

At this time, the undeposited parylene molecules are trapped by the liquid cold trap 7 that communicates with the first deposition unit 6.

A protective layer 4 may be further formed using the second deposition unit 8 illustrated in FIG. 10 either before or after the formation of the encapsulation portion 3. The protective layer 4 is made of silicon oxide, silicon nitride or silicon oxynitride, etc.

The present invention may provide the following advantages.

First, a front emission type organic light-emitting device can be manufactured using the encapsulation portion made of the parylene polymer according to the present invention. To manufacture the front emission type device, an encapsulation portion that is transparent and resistant to water is required and such transparent and water-resistant protective layer can be made using the parylene polymer.

Second, a flexible organic light-emitting device can be manufactured. The encapsulation portion made of the parylene polymer has more flexibility, compared to that made of silicon nitride, thus being more advantageous in manufacturing a flexible organic light-emitting device.

Third, production costs can be lowered by using the apparatus for forming the encapsulation portion according to the present invention. The apparatus according to the present invention has constitutional elements of just a chamber that is a deposition unit and a heater for supplying a material of the encapsulation portion, i.e., the apparatus has a simple structure. Further, the costs of the constitutional elements are low, compared to those in large area ICP-CVD, CCP-CVD, ECR-CVD, which are expensive semiconductor equipment.

Fourth, lifetime and efficiency of the organic light-emitting device can be increased using the encapsulation portion made of the parylene polymer according to the present invention. Since the encapsulation portion according to the present invention is less reactive interface with the second electrode layer that is a cathode electrode and has a lower stress and more excellent adhesion than an encapsulation portion made of silicon nitride, an organic light-emitting device can have an increased lifetime by using the encapsulation portion according to the present invention. Further, a front emission type device can have increased light-emitting efficiency due to high transmittance of the encapsulation portion.

Fifth, by forming a protective layer made of silicon oxide, silicon nitride, or silicon oxynitride, in addition to the encapsulation portion made of the parylene polymer, penetration of water or air can be further prevented, and thus, the lifetime of the organic light-emitting device can be maximized.

While the present invention has been particularly illustrated and described with reference to exemplary embodiments thereof, it will be understood by those of ordinary skill in the art that various changes in form and details may be made therein without departing from the spirit and scope of the present invention as defined by the following claims.

1. An organic light-emitting device, comprising:
a substrate;
an organic light-emitting portion comprising an organic light-emitting diode (OLED) arranged on a surface of the substrate; and
an encapsulation portion comprising parylene polymer and arranged to cover the organic light-emitting portion.

2. The organic light-emitting device of claim 1, the OLED comprises:
a first electrode layer;
an organic layer comprising at least an organic light-emitting layer; and
a second electrode layer sequentially arranged on the substrate, the first electrode layer and the substrate both being transparent.

3. The organic light-emitting device of claim 1, the OLED comprises:
a first electrode layer;
an organic layer comprising at least an organic light-emitting layer; and
a second electrode layer sequentially arranged on the substrate, the second electrode layer being transparent.

4. The organic light-emitting device of claim 1, the parylene polymer comprises a material selected from the group consisting of parylene N, parylene D and parylene C.

5. The organic light-emitting device of claim 1, further comprising a protective layer covering the organic light-emitting portion, the protective layer comprising a material selected from the group consisting of silicon oxide, silicon nitride and silicon oxynitride.

6. The organic light-emitting device of claim 1, the substrate further comprising at least one thin film transistor.

7. A method, comprising:
forming at least one organic light-emitting portion comprising an OLED on a surface of a substrate;
forming a gaseous parylene monomer from a parylene powder; and
depositing the gaseous parylene monomer on the at least the one organic light-emitting portion to form an encapsulation portion made of a parylene polymer.

8. The method of claim 7, the forming of the gaseous parylene monomer comprises:
vaporizing the parylene powder to form parylene dimer by a first heating; and
pyrolizing the parylene dimer to form the gaseous parylene monomer by a second heating.

9. The method of claim 8, the first heating being performed by heating the parylene powder to 130 to 200° C.

10. The method of claim 8, the pyrolizing the parylene dimer being performed by heating the parylene dimer to 500 to 700° C.

11. The method of claim 7, further comprising depositing a protective layer to cover the organic light-emitting portion, the protective layer comprising a material selected from the group consisting of silicon oxide, silicon nitride and silicon oxynitride.

12. An apparatus, comprising:
at least one heating unit adapted to convert parylene powder to a gaseous parylene monomer; and
at least one first deposition unit comprising a substrate and in communication with the heating unit, the first deposition unit being adapted to condense the gaseous parylene monomer onto a surface of the substrate resulting in a film on the substrate.

13. The apparatus of claim 12, the at least one heating unit comprises:
a first heating unit adapted to convert the parylene powder to a parylene dimer by heating; and
a second heating unit adapted to pyrolize the parylene dimer to form the gaseous parylene monomer.

14. The apparatus of claim 13, wherein the first heating unit and the second heating unit are sequentially connected to the first deposition unit.

15. The apparatus of claim 13, wherein the first heating unit and the second heating unit are arranged within the first deposition unit.

16. The apparatus of claim 12, further comprising a liquid cold trap adapted to trap undeposited parylene molecule, the liquid cold trap communicating with the first deposition unit.

17. The apparatus of claim 12, the first deposition unit being insulated from the heating unit.

18. The apparatus of claim 12, further comprising a second deposition unit adapted to deposit a protective layer comprising a material selected from the group consisting of silicon oxide, silicon nitride and silicon oxynitride on to the substrate, the second deposition unit communicating with the heating unit or the first deposition unit.

19. The apparatus of claim 13, one heating unit being arranged at one side of the first deposition unit, the apparatus comprising a second heating unit essentially identical to the first heating unit and arranged at an opposite side of the first deposition unit.

20. The apparatus of claim 12, the substrate being arranged vertically within the first deposition unit, normal to a surface of the substrate being horizontal.
